(19) United States
(12) Patent Application Publication
(10) Pub. No.: US 2024/0283419 A1
(43) Pub. Date: Aug. 22, 2024

(54) TRANSIMPEDANCE GAIN CONTROL

(71) Applicant: Semtech Corporation, Camarillo, CA (US)

(72) Inventors: Pasqualino Michele VISOCCHI, Haverhill (GB); Ryan Patrick MACDONALD, Kanata (CA)

(21) Appl. No.: 18/170,822

(22) Filed: Feb. 17, 2023

(51) Int. Cl. H03G 3/30; H03F 1/02

(52) U.S. Cl. CPC H03G 3/3084; H03F 1/0205

(57) ABSTRACT

This application describes apparatus and method for transimpedance gain control. A transimpedance amplifier circuit is described with a transimpedance amplifier having an input node for receiving an input current. A variable shunt resistance is connected to the input node and a controller is operable to controllably vary an open-loop transimpedance gain of the transimpedance amplifier and also the resistance of the variable shunt resistance so as to vary a closed-loop transimpedance gain of the transimpedance amplifier.

### TECHNICAL FIELD

The present disclosure is related to apparatus and methods for gain control in a transimpedance amplifier.

### BACKGROUND

Transimpedance amplifiers (TIAs) are used in a variety of different applications, for instance TIAs are commonly used in optical receivers for optical communication systems.

Within an optical communication link, data is generally transmitted from an optical source with information encoded by some suitable coding, such as amplitude modulation. This data propagates down an optical path, for example via optical fibre, and is detected by an optical receiver consisting of an optical detector, such as a PIN diode or Avalanche Photo Diode (APD), followed by an electronic low noise amplifier, in the form of a TIA. The optical detector converts the optical signal from light to a current output, and the TIA coverts and amplifies the current to a voltage output. It is generally desirable that the TIA has a very low input referred noise (IRN) to enable the smallest input signal to be detected and, as such, maximise the length of the data channel.

However, generally it is also desirable that the optical receiver can be capable of detecting large optical signals, e.g. resulting from a minimum length of the data channel. Under these conditions the signal would not be limited by IRN but by the capability of the TIA to reproduce the input current signal without the introduction of significant distortion. Under these conditions, the optical receiver would be experiencing an ‘overload’ condition. This wide dynamic range requirement of a TIA is often achieved by the use of an Automatic Gain Control (AGC) that varies the resistance of a feedback element of the TIA.

This resistance variation can be achieved by the use of an nFET operated in the triode region of operation. However, an nFET in the feedback path can introduce undesirable parasitics, such as excessive capacitance at the sensitive input node of the TIA, which would compromise both IRN and bandwidth.

Embodiments of the present disclosure relate to methods and apparatus for gain control of a TIA that address at least some of the above mentioned issues.

### SUMMARY

According to some embodiments there is provided a transimpedance amplifier circuit comprising: a transimpedance amplifier with an input node for receiving an input current; a variable shunt resistance connected to the input node; and a controller operable to controllably vary an open-loop transimpedance gain of the transimpedance amplifier and also the resistance of the variable shunt resistance so as to vary a closed-loop transimpedance gain of the transimpedance amplifier.

The transimpedance amplifier may comprise an input transistor with a control terminal connected to the input node, the input transistor being in series with a first transistor in a first circuit branch. The controller may be operable to controllably vary a control current injected into the first circuit branch to controllably vary the open-loop transimpedance gain. In some examples, the transimpedance amplifier circuit may comprise a control transistor configured to be controlled by a control voltage from the controller to provide the control current.

In some examples, a second transistor may be connected in series with the control transistor in a second circuit branch, and the variable shunt resistance may comprise a resistor connected between the input node and a node of the second circuit branch between the second transistor and the control transistor. A control loop may be configured to control the second transistor to maintain a DC voltage across the resistor equal to zero. The control loop may comprise an op-amp connected in parallel with resistor. The controller may be configured to set the control voltage to zero to provide a high-gain mode and is configured to set the control voltage to a non-zero bias voltage to provide a low-gain mode.

In some implementations, the controller may be configured to vary the closed-loop transimpedance gain of the transimpedance amplifier based on an indication of input current at the input node.

Aspects also relate to an optical receiver comprising the transimpedance amplifier circuit of any of the embodiments described herein and a photodetector configured to receive an input optical signal and output a photocurrent to the input node of the transimpedance amplifier.

In another aspect, there is provided a transimpedance amplifier circuit comprising: a transimpedance amplifier with an input node for receiving an input current; a variable shunt resistance connected to the input node.

In a further aspect there is a provided a transimpedance amplifier circuit comprising: a transimpedance amplifier with an input node for receiving an input current, the transimpedance amplifier comprising an input transistor in series with a cascode transistor in a first circuit branch and a second transistor configured to inject a controllably variable control current into the first circuit branch to vary an open-loop transimpedance gain of the transimpedance amplifier.

In a further aspect there is a transimpedance amplifier circuit comprising: a transimpedance amplifier with an input node for receiving an input current; a variable shunt resistance connected to the input node; and a controller operable to controllably vary the resistance of the variable shunt resistance so as to vary a closed-loop transimpedance gain of the transimpedance amplifier. The transimpedance amplifier may comprise a circuit branch having first and second transistor in series, wherein the variable shunt resistance comprises a shunt resistor coupled between the input node and a node located between the first and second transistors and wherein the controller is configured to control a current through the first transistor so as to control the variable shunt resistance.

### BRIEF DESCRIPTION OF THE DRAWINGS

To better explain various embodiments and examples of the present disclosure and the principles, example implementation and operation thereof, reference will now be made, by way of example, to the following drawings, in which:

FIG. 1 illustrates one example of a conventional TIA arrangement for an optical receiver;

FIG. 2 illustrates an example of a TIA arrangement according to an embodiment in an example of an optical receiver;

FIG. 3 illustrates one example of TIA with a controllably variable open-loop transimpedance gain; and

FIG. 4 illustrates one example of TIA with a controllably variable input shunt resistance.

### DETAILED DESCRIPTION

Embodiments of the present disclosure relate to methods and apparatus for gain control in a transimpedance amplifier (TIA).

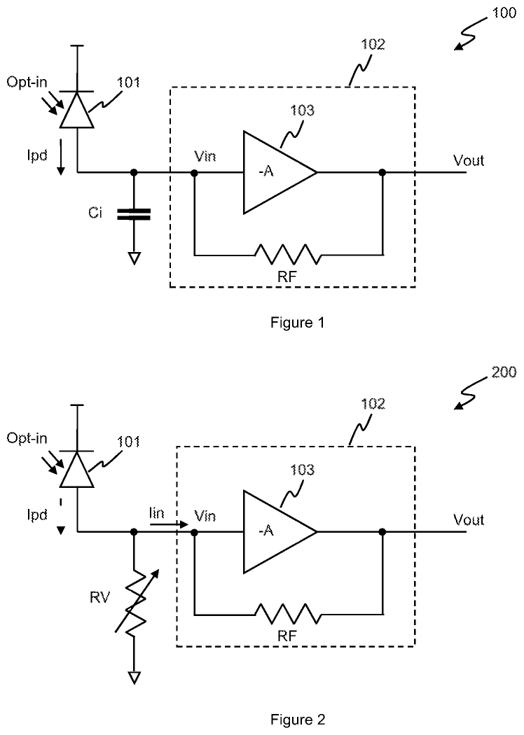

FIG. 1 illustrates one example of a conventional TIA arrangement for an optical receiver. The optical receiver 100 includes a photodiode 101, such as a PIN or APD diode, that receives the optical input Opt-in and generates a corresponding photocurrent Ipd. The output of the photodiode 101 is connected to the input of a TIA 102, which converts the photocurrent Ipd into an output voltage Vout. The TIA has a gain block 103 in the forward signal path and a feedback resistance RF.

The closed-loop transimpedance gain T_{Z} of the TIA is defined by:

$${T}_{Z} = \frac{Vout}{Ipd} \qquad Eqn . 1$$

which can be determined to be:

$${T}_{Z} = ( \frac{R F}{( \frac{1 + {A}_{V}}{{A}_{V}} ) + \frac{R F}{{A}_{T}}} ) \qquad Eqn . 2$$

where A_{V} represents the open-loop voltage gain, A_{T} represents the open-loop transimpedance gain and RF is the value of the feedback resistance. If the open-loop transimpedance gain A_{T} and voltage gain A_{V} are very large, this would result in a virtual earth at the input node and the value of the closed-loop transimpedance gain T_{Z} would be very close to RF.

The closed-loop input impedance, Rin, of the TIA is defined as:

$$Rin = \frac{V in}{Ipd} \qquad Eqn . 3$$

where Vin is the voltage at the input. The closed-loop input impedance can be determined to be:

$$Rin = \frac{R F}{{A}_{V}} ( \frac{1}{( \frac{1 + {A}_{V}}{{A}_{V}} ) + \frac{R F}{{A}_{T}}} ) \qquad Eqn . 4$$

Again, if the open-loop transimpedance gain A_{T} and voltage gain A_{V} are very large, this would result in a virtual earth at the input node and the value of Rin would be very close to zero.

The closed-loop transimpedance gain and input impedance are both dependent upon the same scaling factor y:

$$y = ( \frac{1}{( \frac{1 + {A}_{V}}{{A}_{V}} ) + \frac{R F}{{A}_{T}}} ) \qquad Eqn . 5$$

$$so that :$$

$${T}_{Z} = RF \cdot y \qquad Eqn . 6$$

$$and :$$

$$Rin = \frac{RF \cdot y}{{A}_{v}} \qquad Eqn . 7$$

The input referred noise (IRN) of the TIA is also largely determined by the noise contribution, ‘Iₙ’ of the feedback resistor, as:

$${I}_{n}^{2} = \frac{4 k T}{R F} \qquad Eqn . 8$$

where, as will be understood by skilled in the art, k is the Boltzmann constant and T is temperature.

It can be seen that a low IRN generally requires a high value RF of feedback resistance, but that a high value of feedback resistance RF results in a high TIA gain, which reduces the ability of the TIA to receive large input currents without overload and hence reduces the dynamic range of the TIA.

One known method to achieve a wide dynamic range is to controllably vary the value of the feedback resistance RF, so as to reduce the value of RF for higher input current to reduce the TIA gain and prevent distortion. In particular a transistor, such as an nFET, may be provided as part of the feedback resistance, i.e. in series with the feedback resistor. The nFET can be controlled to provide a variable resistance so as to allow the overall value of the feedback resistance to be varied. However, including such an nFET in the feedback path can introduce additional parasitic capacitance Ci at the input node, which is undesirable.

In at least some embodiments of the present disclosure, a variable shunt resistance is connected to the input node to allow control of the transimpedance gain.

FIG. 2 illustrates one example of a TIA according to an embodiment, in the example of an optical receiver 200.

The optical receiver 200 of FIG. 2 again has a photodiode 101 arranged to receive the input optical signal Opt-in and generate a corresponding photocurrent Ipd. A TIA 102, with a forward gain block 103 and feedback resistance RF is coupled to output of the photodiode 101, but, in the example of FIG. 2, a variable resistance RV is connected between the input to the TIA and a defined voltage, in this example ground.

As discussed above, if the value of the feedback resistance RF is very high, this can result in a virtual earth at the input of the TIA. However, as, practically, the open-loop transimpedance gain is always finite in value, the input to the TIA is not an ideal virtual earth, and thus a proportion of the input current Ipd from the optical detector can be shunted away from the TIA input via the variable resistance RV. Shunting some of the photocurrent Ipd to earth reduces the amount of input current Iin applied to the TIA, which thus enables a gain control function that can be implemented in the presence of a large optical input. The variable resistance RV can thus be seen as a variable shunt resistance.

If the value of the variable resistance is set as x·RF, then the gain T_{ZX} of the TIA of FIG. 2 is given by:

$${T}_{Z X} = RF \cdot y ( \frac{x}{x + \frac{y}{A v}} ) \qquad Eqn . 9$$

where y is the factor of equation 5.

The introduction of the shunt resistance RV thus introduces a scaling factor SF_{X} into the transimpedance gain, where the scaling factor SF_{X} is equal to:

$$S {F}_{X} = ( \frac{x}{x + \frac{y}{{A}_{V}}} ) \qquad Eqn . 10$$

It can be seen that if the variable resistance RV were open circuit, so the variable resistance is effectively infinite and the value x is ∞, then the gain scaling factor SF_{X} would be unity and the closed-loop gain would be a maximum value, as determined by equation 2 above.

In addition, the introduction of the input shunt variable resistance RV also modifies the input resistance Rin_{X} as:

$$R i {n}_{X} = \frac{RF \cdot y}{{A}_{V}} ( \frac{x}{x + \frac{y}{{A}_{V}}} ) \qquad Eqn . 11$$

which thus also is scaled by the same scaling factor SF_{X} of equation 10. Thus, if the variable resistance RV were open circuit, so the variable resistance is effectively infinite and the value x is ∞, then the gain scaling factor SF_{X} would be unity and the input maximum input resistance would be given by equation 4 above.

Purely for the purposes of illustration, consider that the value of the feedback resistance is 600Ω, the open-loop voltage gain A_{V} is 25 and the open-loop transimpedance gain A_{T} is 10 kΩ. In this case, if the variable shunt resistance RV were open-circuit, i.e. an effective resistance value of ∞ so that the scaling factor SF_{X} is unity, the closed-loop transimpedance gain T_{ZX} would be at a maximum value of 545.50 and the input resistance Rin_{X} would be at a maximum value of 21.8Ω. Were, however, the variable shunt resistance controllably varied to a value of 100Ω, so that x=⅙, the closed loop transimpedance gain T_{ZX} would have a value of 447.9Ω and the input resistance Rin_{X} would have a value of 17.9Ω. In this example a reduction of 1.7 dB is thus achieved from the maximum transimpedance gain, with a corresponding reduction in input resistance.

Embodiments of the present disclosure thus provide a gain control function through use of a variable shunt resistance coupled to the input node of the TIA.

In at least some embodiments, additional gain control functionality may be implemented by controllably varying the open-loop transimpedance gain A_{T} of the TIA.

Referring back to equation 9, it can be seen the closed-loop transimpedance gain depends on the scaling factor y of equation 5 and also the scaling factor SF_{X} of equation 10 (which itself has a dependence on the factor y).

If it is assumed that (1+A_{V})/A_{V} is approximately unity, then the closed-loop transimpedance gain T_{ZX} is given by:

$${T}_{Z X} \approx ( \frac{R}{1 + \frac{RF}{{A}_{T}}} ) ( \frac{x}{x + \frac{y}{{A}_{V}}} ) \qquad Eqn . 12$$

$$where$$

$$y \approx \frac{1}{1 + \frac{R F}{{A}_{T}}}$$

It can be seen that a decrease in the open-loop transimpedance gain A_{T} could result in a reduction in the closed-loop transimpedance gain T_{ZX}. For instance, if a factor n, could be introduced, so as to reduce the open-loop transimpedance gain according to A_{T}/(1+n), then the resulting closed-loop transimpedance gain T_{ZXn} would be given by:

$${T}_{Z X n} \approx ( \frac{RF}{1 + \frac{R F ( 1 + n )}{{A}_{T}}} ) ( \frac{x}{x + \frac{y}{{A}_{V}}} ) \qquad Eqn . 13$$

The closed-loop transimpedance gain T_{ZXn} would be maximum when the value x is ∞, i.e. when the variable shunt resistance RV is open-circuit, and when the value n is zero, and can be reduced by reducing the resistance of the shunt resistance RV and by increasing the value of the parameter n.

For the situation when the variable resistance RV is open-circuit, the additional gain reduction due to the parameter n can be seen as:

$$\frac{{T}_{Z∞ , 0}}{{T}_{Z ∞ , n}} = \frac{( \frac{{A}_{T}}{{R}_{F}} + 1 + n )}{( \frac{{A}_{T}}{{R}_{F}} + 1 )} \qquad Eqn . 14$$

where T_{Z∞,0} is the closed-loop transimpedance gain with x=∞ and n=0 and T_{Z∞,n} is the closed-loop transimpedance gain with x=∞ and n being non-zero.

Based on the same example parameters as discussed previously, i.e. a value of the feedback resistance of 600δ, an open-loop voltage gain A_{V} of 25 and an open-loop transimpedance gain A_{T} of 10 kΩ, then:

$$\frac{{T}_{Z∞ , 0}}{{T}_{Z∞ , n}} = \frac{17.67 + n}{17.67} \qquad Eqn . 15$$

For these example parameters, Table 1 illustrates how the closed-loop transimpedance gain may vary with the value of n for the example with the shunt resistance value RV=∞ and also the combined gain reduction with the shunt resistance value RV=100Ω.

TABLE 1

| | Gain change from | Gain change from |
|---|---|---|
| Value on n | maximum with RV = ∞ | maximum with RV = 100Ω |
| 1.0 | −0.48 dB | −2.34 dB |
| 1.5 | −0.71 dB | −2.59 dB |
| 2.0 | −0.93 dB | −2.81 dB |
| 2.5 | −1.15 dB | −3.03 dB |
| 3.0 | −1.36 dB | −3.24 dB |

There are various ways in which the open-loop transimpedance gain A_{T} may be controllably varied.

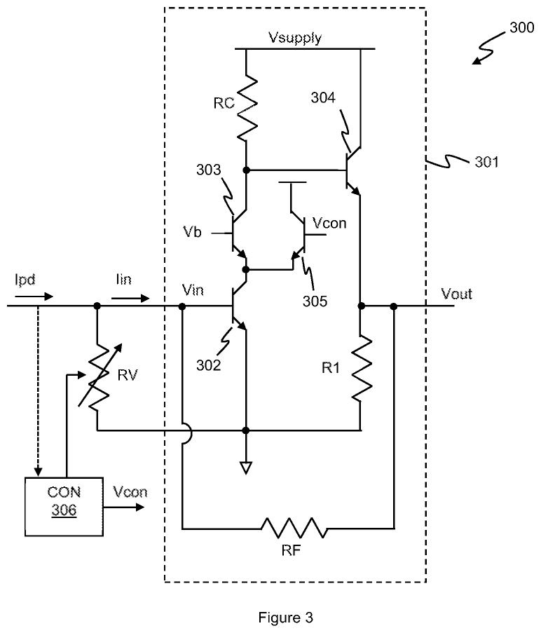

FIG. 3 illustrates one example of a TIA arrangement 300 with a controllably variable open-loop transimpedance gain A_{T}. The TIA arrangement 300 allows the open-loop transimpedance gain A_{T} to be varied whilst maintaining the open-loop voltage gain A_{V}.

The TIA 301 has an input transistor 302 with its control terminal, i.e. its base terminal, connected to the TIA input. Transistor 302 is arranged in series in a first circuit branch with transistor 303, to act a cascode device, with its base connected to a bias voltage Vb. The cascode transistor 303 is coupled to the supply voltage Vsupply via a collector resistance RC. An output transistor 304 has its base connected to a node of the first circuit branch between the collector resistance RC and cascode transistor 303.

A transistor 305 is driven by a control voltage Vcon, which may be generated by a controller 306 as will be discussed in more detail below, so as to controllably inject a controlled current into the first circuit branch between transistors 303 and 302. The transistor 305 may be referred to as a control transistor for generating a variable control current to be injected into the first circuit branch.

If the control voltage Vcon is zero, so that control transistor 305 is inactive, the collector current of the input transistor is the same as that of the cascode transistor 303 (assuming negligible loss in the cascode transistor 303). In this case, if the variable shunt resistance is open-circuit, i.e. RV=∞, the open-loop transimpedance gain A_{T} and open-loop voltage gain A_{V} would be given by:

$${A}_{T} = {h}_{fe} \cdot RC and {A}_{V} = \frac{R C}{{r}_{e}} \qquad Eqn . 16$$

where h_{fe} is the current gain of input transistor 302 and rₑ is the emitter resistance of the input transistor 302.

If, however, the control voltage Vcon were set to be equal to the bias voltage Vb, the transistor 305 would be active and would contribute current to collector of input transistor 302. In this case, the collector current of transistor 303 would remain constant, determined by (Vsupply−2V_{be})/RC. The addition of current from the transistor 305 thus results in an increased collector current in the input transistor 302. If the transistor 305 is scaled with respect to transistor 303 by a factor of n, i.e. so that the current through transistor 305 is n times the current through transistor 303, then the collector current of the input transistor 302 will increase by a factor of (1+n).

In this case, the current gain of the input transistor 302 will effectively reduce to h_{fe}/(1+n), the AC voltage signal at the collector of transistor 303 will increase to RC(1+n) and the effective emitter resistance re of the input transistor 302 will reduce to rₑ/(1+n). In this case, the open-loop transimpedance gain A_{T} and open-loop voltage gain A_{V} of the TIA 301 would be given by:

$${A}_{T} = \frac{{h}_{fe} \cdot RC}{( 1 + n )} and {A}_{V} = \frac{R C}{{r}_{e}} \qquad Eqn . 17$$

In other words, the open-loop transimpedance gain A_{T} reduces as a function of n, which in this example depends on the scaling factor between the transistors 303 and 305, but the open-loop voltage gain A_{V} remains constant with a variation in n.

The closed-loop transimpedance gain T_{ZXn} can, assuming that (1+A_{V})/A_{V}≈1, be given by:

$${T}_{Z X n} \approx ( \frac{RF}{1 + \frac{R F ( 1 + n )}{{h}_{fe} R C}} ) ( \frac{x}{x + \frac{y {r}_{e}}{R C}} ) \qquad Eqn . 18$$

$$where$$

$$y \approx \frac{1}{1 + \frac{R F ( 1 + n )}{{h}_{fe} R C}}$$

Equation 18 shows that the closed-loop transimpedance gain T_{ZXn} reduces as a function of x and n.

In addition, the closed-loop input resistance is given by:

$$R i {n}_{X n} \approx \frac{RF \cdot {r}_{e}}{R C} ( \frac{1}{1 + \frac{R F ( 1 + n )}{{h}_{fe} R C}} ) ( \frac{x}{x + \frac{y {r}_{e}}{R C}} ) \qquad Eqn . 19$$

It can be seen that the input resistance scaling factor is dependent upon the factor y, as is the case for the scaling factor for the closed-loop gain.

However, as the operation of the control transistor 305 is to increase the current in the input transistor 302 when enabled, this also has the advantageous effect of, in practice, increasing the input resistance of the TIA by generating a greater voltage across the parasitic emitter resistor.

A maximum closed-loop transimpedance gain T_{ZXn} may thus be enabled, by setting the control voltage Vcon to zero, so that the contribution from the n scaled control transistor 305 is zero, and also by controlling the variable shunt resistance RV to some maximum value, for instance open-circuit. This may correspond to a high-gain, high-sensitivity mode of operation. A minimum closed-loop transimpedance gain, for implementing a low-gain, low sensitivity mode, e.g. possible overload conditions, can be enabled by setting the control voltage Vcon to Vb, so that transistor 305 contributes n times the current of transistor 303, and also be setting the variable shunt resistance RV to some minimum value, which may be a relatively low value that may be a fraction of the feedback resistance RF.

Preferably, the TIA may be configured so as to have a relatively low IRN when operating in the high-gain, high sensitivity mode, whilst having a sufficient gain reduction in the low gain mode to provide sufficient dynamic range for the intended application. The value n of the scaling factor of the transistors 303 and 305 may thus be set accordingly, along with other parameters of the TIA.

The gain of the TIA, e.g. the mode of operation, may be controlled by a gain controller 306. The gain controller 306 may receive or derive some indication of the level of input signal and control the gain of the TIA accordingly by controlling the resistance of the variable shunt resistance RV and the control voltage Vcon. The gain controller 306 may thus implement an automatic gain control (AGC) function. For instance, the gain controller 306 may include, or be responsive to, a suitable current monitor that monitors the photocurrent or input current to the TIA. Such a current monitor may provide an indication of AC current, such as AC rms value, e.g. derived from a rectification process, or a peak AC current value. In some case, if the relevant application has a well-controlled transmitter extinction ratio, the current monitor could provide an indication of DC current. In some examples, the indication of current may be compared to one or more thresholds, with the gain being controlled accordingly.

In some implementations the gain controller 306 may be configured to control the gain to swap between the maximum and minimum gain levels depending on the input current, i.e. to swap between the high-gain and low-gain modes of operation. In some implementations, however, the gain may be varied is a relatively continuous manner, e.g. by controlling the control voltage Vcon to some intermediate voltage between zero and Vb, so that the transistor 305 contributes a non-zero current which is less than n times the current of transistor 303 and/or by setting the resistance of the variable shunt resistor RV to some intermediate value between the maximum and minimum resistance values. In at least some embodiments the open-loop transimpedance gain A_{T} and the resistance of the variable shunt resistor RV may be controlled together.

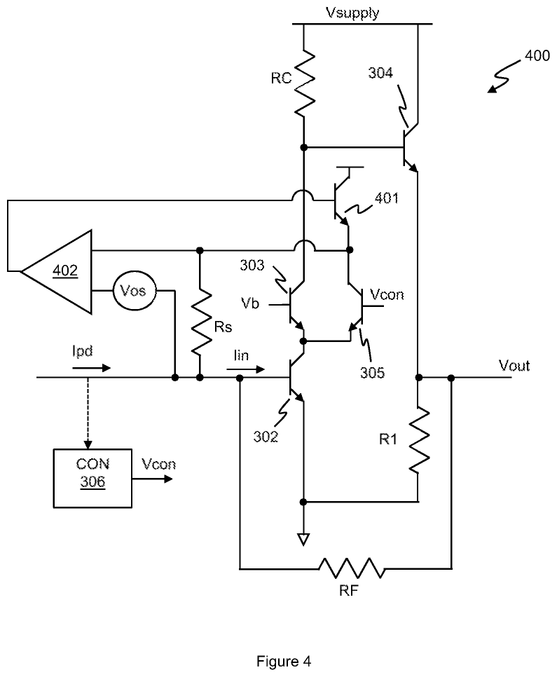

FIG. 4 illustrates one example of a TIA arrangement 400 according to an embodiment with control over the open-loop transimpedance gain A_{T} and the resistance of the variable shunt resistance RV.

The example of FIG. 4 includes an input transistor 302, cascode transistor 303 and output transistor 304 in a similar arrangement as discussed with reference to FIG. 3. However, in the example of FIG. 4, the control transistor 305 controlled by the control voltage Vcon is in series with transistor 401 in a second circuit branch. The transistor 401 has its control terminal, i.e. base, driven by op-amp 402.

The shunt resistor, which in this case is a resistor with a fixed nominal resistance Rs, is connected between the TIA input and a node of the second circuit branch between transistors 401 and 305. This node is also connected to an input of the op-amp 402, with the other input of the op-amp being connected on the other side of the shunt resistor Rs.

In this example, if the control voltage Vcon is zero, the transistor 305 is inactive and so, by default, the transistor 401 is also inactive. To ensure that transistor 401 remains inactive, an offset voltage Vos, may be applied to an input of op-amp 402 to counteract any offset that would otherwise be experienced at the inputs of the op-amp 402. Thus, as the transistor 401 is inactive in this state, with an effective emitter resistance rₑ=∞, the shunt resistor Rs is effectively isolated and open-circuit and thus this shunt path presents an effective resistance RV=∞. Setting the control voltage Vcon to zero thus provides the maximum gain, i.e. a high-gain, high sensitivity mode, with RV=∞ and n=0.

To provide a gain reduction and transition to the low-gain, low sensitivity mode, the control voltage Vcon may be increased up to the voltage Vb. As the control voltage Vcon increases, the collector current of transistor 305 will increase, which will contribute additional current to the input transistor 302, with a resultant decrease in open-loop transimpedance gain as discussed with reference to FIG. 3. In addition, the increased collector current in transistor 305 increase will lead to an increase in the collector current of transistor 401, which results in a reduction in emitter resistance. Assuming that, when the control voltage Vcon is equal to Vb, the emitter resistance rₑ of transistor 401 is very much lower than the resistance Rs of the shunt resistor, the resultant resistance of the shunt path will be dominated by the value of the fixed shunt resistance and thus the value of the variable shunt resistance will be substantially equal to Rs when the control voltage is equal to Vb. The value of resistance for the fixed shunt resistance may be selected, with respect to the feedback resistance, to thus provide a desired minimum value for the variable shunt resistance RV, for instance for the example discussed above if the value of the feedback resistance is 6000, the value Rs of the shunt resistor could be 100Ω, although it will be understood that these values are purely for the purposes of explanation and various different resistance values could be used depending on the application.

During the operation where the control voltage Vcon varies and the emitter resistance rₑ of transistor 401 varies, the control loop comprising op-amp 402 operates to ensure that the DC voltage between the terminal of the shunt resistor Rs is maintained at zero. This provides the input variable shunt resistance with an AC ground termination only.

A controller 306 may thus control the control voltage Vcon to vary from zero to Vb in a similar manner as discussed with reference to FIG. 3.

In the embodiment of FIG. 4, the variable shunt resistance is thus controlled by controlling, via transistor 305, the emitter resistance rₑ of transistor 401, and hence the shunt path comprising the shunt resistor Rs. This allows a variation in the shunt resistance to be implemented, without using a unipolar device such as FET transistor that would introduce undesirable parasitics. Control of the current through transistor 305 also provides control over the open-loop transimpedance gain which provides an increased amount of gain control.

Preferably, for correct operation throughout the dynamic range, the DC bias voltage Vb applied to the base of transistor 305 may be controlled to be equal to ßV_{be}, where ß<2, which allows the DC voltage at the collector of transistor 303 to be at V_{be}. In this case, when the control voltage Vcon=Vb=ßV_{be}, i.e. in the low gain state, the collector-emitter voltage V_{ce} of the input transistor 302 would be equal to (ß−1)V_{be}. If, for example, ß was equal to 1.5, then the collector-emitter voltage V_{ce} of the input transistor 302 would be 0.5V_{be} and the collector-emitter voltage V_{ce} of transistor 305 would be (V_{be}−0.5V_{be}=) 0.5V_{be}. It will be understood, however, that value of ß=1.5 is not exclusive, i.e. other values could be implemented in some cases, although consideration for transistor breakdown voltage and the optimum voltage distribution of V_{ce} between the input transistor 302 and transistor 305 may be taken into account so that zero DC voltage occurs between the terminals of the shunt input resistor Rs and that the collector of transistor 305 is fixed at V_{be}.

In addition, to ensure the preservation of the lowest IRN, the loading of the TIA input node by the Op-Amp 402 may be minimised by the use of high value resistors facilitated by the use of FET based inputs. Also, the use of low-pass filtering could help in ensuring minimum impact on IRN, e.g. from data pattern dependency of the Op-Amp control loop, depending upon the application and data rate. The application of the input offset voltage V_{OS} could, in some cases, be achieved by an appropriate choice of input FET offset geometries to obtain a fixed value or the use of a programmable current source to obtain a variable voltage offset.

Note that FIGS. 3 and 4 represent implementations in bipolar technology, but in other examples, other transistor technologies could be implemented.

In general therefore, at least some embodiments relate to gain control for a transimpedance amplifier, for example as part of an optical receiver, in which the closed-loop transimpedance gain may be controllably varied by controlling the resistance of an input shunt resistance through controllably varying the open-loop transimpedance gain, whilst maintaining the open-loop voltage gain. The gain may be controlled based on an indication of input signal for the TIA to implement an automatic gain control function.

It will be understood that the examples and embodiments described above are given by way of example only and those skilled in the art will understand that modifications, variations, additions or alterations may be made to specific embodiments described, or alternative embodiments may be implemented, without departing from the scope of the appended claims.

It should be noted that as used herein, unless expressly stated otherwise, the word “comprising” does not exclude the presence of other elements or steps other than those listed, references to an element or feature in the singular does not exclude the possibility of a plurality of such elements or features, and that recitation of different features or elements in the appended claims does not necessarily imply separate components; a single component or unit may fulfil the function of several elements recited in a claim. Any reference signs in the appended claims shall not be construed so as to limit their scope.

1. A transimpedance amplifier circuit comprising:
a transimpedance amplifier with an input node for receiving an input current;
a variable shunt resistance connected to the input node; and
a controller operable to controllably vary an open-loop transimpedance gain of the transimpedance amplifier and also the resistance of the variable shunt resistance so as to vary a closed-loop transimpedance gain of the transimpedance amplifier.

2. The transimpedance amplifier circuit of claim 1 wherein the transimpedance amplifier comprises an input transistor with a control terminal connected to the input node, the input transistor being in series with a first transistor in a first circuit branch and wherein the controller is operable to controllably vary a control current injected into the first circuit branch to controllably vary the open-loop transimpedance gain.

3. The transimpedance amplifier circuit of claim 2 comprising a control transistor configured to be controlled by a control voltage from the controller to provide said control current.

4. The transimpedance amplifier circuit of claim 3 further comprising a second transistor in series with said control transistor in a second circuit branch, wherein the variable shunt resistance comprises a resistor connected between the input node and a node of the second circuit branch between the second transistor and the control transistor.

5. The transimpedance amplifier circuit of claim 4 further comprising a control loop configured to control the second transistor to maintain a DC voltage across the resistor equal to zero.

6. The transimpedance amplifier circuit of claim 5 wherein the control loop comprises an op-amp connected in parallel with resistor.

7. The transimpedance amplifier circuit of claim 6 wherein the controller is configured to set the control voltage to zero to provide a high-gain mode and is configured to set the control voltage to a non-zero bias voltage to provide a low-gain mode.

8. The transimpedance amplifier circuit of claim 1 wherein the controller is configured to vary the closed-loop transimpedance gain of the transimpedance amplifier based on an indication of input current at the input node.

9. An optical receiver comprising the transimpedance amplifier circuit of claim 1 and a photodetector configured to receive an input optical signal and output a photocurrent to the input node of the transimpedance amplifier.

10. A transimpedance amplifier circuit comprising:
a transimpedance amplifier with an input node for receiving an input current;
a variable shunt resistance connected to the input node.

11. A transimpedance amplifier circuit comprising:
a transimpedance amplifier with an input node for receiving an input current, the transimpedance amplifier comprising an input transistor in series with a cascode transistor in a first circuit branch and a second transistor configured to inject a controllably variable control current into the first circuit branch to vary an open-loop transimpedance gain of the transimpedance amplifier.

12. A transimpedance amplifier circuit comprising:
a transimpedance amplifier with an input node for receiving an input current;
a variable shunt resistance connected to the input node; and
a controller operable to controllably vary the resistance of the variable shunt resistance so as to vary a closed-loop transimpedance gain of the transimpedance amplifier.

13. The transimpedance amplifier circuit of claim 12 comprising a circuit branch having first and second transistor in series, wherein the variable shunt resistance comprises a shunt resistor coupled between the input node and a node located between the first and second transistors and wherein the controller is configured to control a current through the first transistor so as to control the variable shunt resistance.
